(19) United States
(12) Patent Application Publication
(10) Pub. No.: US 2025/0021285 A1
(43) Pub. Date: Jan. 16, 2025

(54) DISPLAY DEVICE

(71) Applicant: FUJI CORPORATION, Chiryu (JP)

(72) Inventor: Teruyuki OHASHI, Anjo-shi (JP)

(73) Assignee: FUJI CORPORATION, Chiryu (JP)

(21) Appl. No.: 18/711,759

(22) PCT Filed: Jan. 13, 2022
(86) PCT No.: PCT/JP2022/000962

§ 371 Date: May 20, 2024

(51) Int. Cl. G06F 3/14; G06T 3/40; G06T 7/50; G06V 10/764; G09G 5/373

(52) U.S. Cl. CPC G06F 3/14; G06T 3/40; G06T 7/50; G06V 10/764; G09G 5/373

(57) ABSTRACT

A display device includes a control section to change a size of an image of a board and to display the image on a display section. The image includes one or multiple first portions belonging to a first classification and one or multiple second portions belonging to a second classification different from the first classification. The control section displays the image including the first portion and the second portion on the display section in a case where the size of the image to be displayed on the display section is larger than a predetermined value, and displays the image including the first portion but not including the second portion on the display section in a case where the size of the image to be displayed on the display section is smaller than the predetermined value.

### TECHNICAL FIELD

The technique disclosed in the present description relates to a display device. In particular, the present description relates to a display device that displays an image of a board as a target for executing predetermined processing in a board work machine.

### BACKGROUND ART

JP-A-2019-91774 discloses a component mounting device that captures an image of a component picked up by a nozzle with a camera and displays the captured image on a display section. In this device, a user can specify an outer shape of the component by performing touch input on a display region of the component based on the disposition of terminals or the like of the displayed component.

### BRIEF SUMMARY

### Technical Problem

In a technical field of a device or the like disclosed in JP-A-2019-91774, not only an image of a component to be mounted but also an image of a board to be produced (a final product or a semi-finished product) may be displayed on a display section. Since the size of a component or the like mounted on the board is smaller than the size of the board, when an image of the entire board is displayed, there may be a problem that an important element related to the component or the like mounted on the board is not displayed depending on the display size of the image. The present description proposes a technique capable of providing a user with appropriate information when displaying an image of a board.

### Solution to Problem

A display device disclosed in the present description displays, on a display section, an image of a board as a target for executing predetermined processing in a board work machine. The display device includes a control section configured to change a size of the image of the board and to display the image on the display section. The image includes one or multiple first portions belonging to a first classification and one or multiple second portions belonging to a second classification different from the first classification. A first priority order is assigned to the first classification, a second priority order is assigned to the second classification, and the priority order is an order indicating a degree of priority to be displayed on the display section. The control section executes display control processing of displaying the image including the first portion and the second portion on the display section in a case where the size of the image to be displayed on the display section is larger than a predetermined value, and displaying the image including the first portion but not including the second portion on the display section in a case where the size of the image to be displayed on the display section is smaller than the predetermined value.

In the display device, the image of the board displayed on the display section includes the first classification and the second classification, and the priority order indicating the degree of priority to be displayed on the display section is assigned to these classifications. The control section determines whether to display each of the first portion belonging to the first classification and the second portion belonging to the second classification according to the size of the image of the board displayed on the display section. Therefore, for example, even in a case where the size of the image is smaller (that is, the scale is larger) than the predetermined value, the first portion belonging to the first classification is displayed on the display section by setting a more important element among the elements constituting the image to be displayed as the first portion. As described above, in the display device, by assigning the priority order indicating the degree of priority to be displayed to each classification, it is possible to provide the user with appropriate information without missing the display of the important element even when the size of the image to be displayed is reduced.

### BRIEF DESCRIPTION OF DRAWINGS

FIG. 1 is a schematic diagram illustrating a configuration of a component mounting system.

FIG. 2 is a schematic diagram illustrating a configuration of a component mounter.

FIG. 3 is a block diagram illustrating a configuration of a management device.

FIG. 4 is a flowchart illustrating a content of display control processing.

FIG. 5 is a diagram illustrating an example of a display mode of an image of a board in Example 1.

FIG. 6 is a diagram illustrating another example of the display mode of the image of the board in Example 1.

FIG. 7 is a diagram illustrating another example of the display mode of the image of the board in Example 1.

FIG. 8 is a diagram illustrating another example of the display mode of the image of the board in Example 1.

FIG. 9 is a diagram illustrating another example of the display mode of the image of the board in Example 1.

FIG. 10 is a diagram illustrating an example of a display mode of an image of a board in Example 2.

FIG. 11 is a diagram illustrating another example of the display mode of the image of the board in Example 2.

FIG. 12 is a diagram illustrating another example of the display mode of the image of the board in Example 2.

FIG. 13 is a diagram illustrating another example of the display mode of the image of the board in Example 2.

FIG. 14 is a diagram illustrating another example of the display mode of the image of the board in Example 2.

FIG. 15 is a diagram illustrating another example of the display mode of the image of the board in Example 2.

### DESCRIPTION OF EMBODIMENTS

Main features of an example, which will be described below, will be listed. Technical elements, which will be described below, are each independent technical elements and are designed to exhibit technical usefulness alone or by being combined in various ways, and the combinations are not limited to those described in claims made for the patent application.

In an embodiment of the present technique, the first classification and the second classification may be any of a shape of a sub-board disposed on the board, a shape of a component mounted on the board, a shape of a lead and a bump of the component, a marker indicating a direction of the component, or a character string or a figure printed on the component.

Each classification described above is a main element constituting the image of the board. Therefore, by adopting any of the above-described elements as the first classification or the second classification, more appropriate information can be provided to the user.

In an embodiment of the present technique, in a case where the image includes multiple types of components, the control section may execute the display control processing for the components for each type.

In such a configuration, the display control processing is executed for each type of component. That is, whether to display an element belonging to a predetermined classification is determined for each type of component according to the size of the displayed image. Therefore, the user can easily obtain the content of the image displayed on the display section.

### Example 1

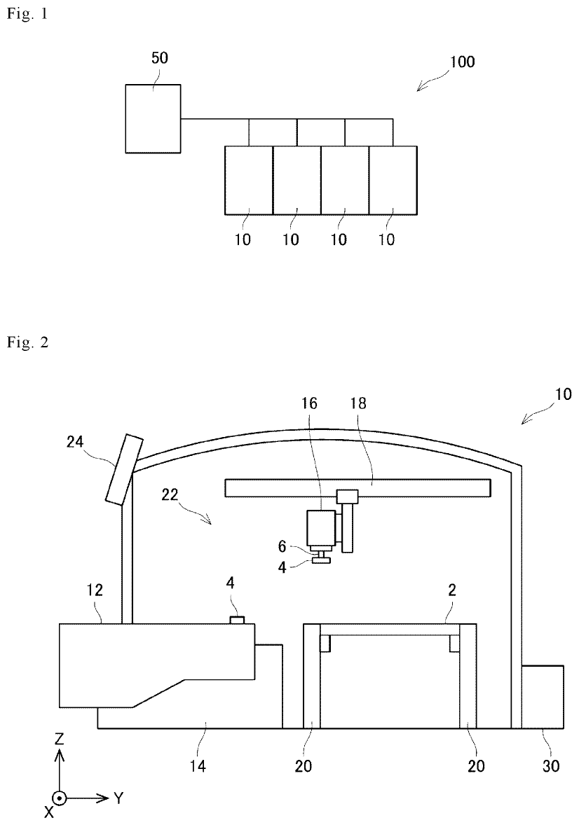

Hereinafter, component mounter 10 of Example 1 will be described. As illustrated in FIG. 1, component mounter 10 is communicably connected to management device 50. Management device 50 is communicably connected to multiple component mounters 10, and manages multiple component mounters 10. Management device 50 and multiple component mounters 10 constitute component mounting line 100. Management device 50 controls entire component mounting line 100 by controlling the operation of each component mounter 10. That is, management device 50 specifies, for each of multiple component mounters 10, the type, position, and the like of electronic component 4 to be mounted on board 2 by component mounter 10, and gives component mounter 10 an instruction about them. When component mounter 10 operates based on the instruction from management device 50, necessary electronic component 4 is mounted on board 2.

Component mounter 10 is a device that mounts electronic component 4 on board 2. Component mounter 10 is also referred to as an electronic component mounting device or a chip mounter. As illustrated in FIG. 2, component mounter 10 includes component mounting section 22, interface device 24, and control device 30. Component mounting section 22 includes multiple component feeders 12, feeder holding section 14, mounting head 16, head moving device 18, and board conveyor 20.

Each component feeder 12 accommodates multiple electronic components 4. Component feeder 12 is detachably attached to feeder holding section 14 and supplies electronic component 4 to mounting head 16. A specific configuration of component feeder 12 is not particularly limited. Each component feeder 12, for example, may be any of a tape-type feeder for accommodating multiple electronic components 4 on a wound tape, a tray-type feeder for accommodating multiple electronic components 4 on a tray, or a bulk-type feeder for accommodating multiple electronic components 4 randomly in a container.

Feeder holding section 14 includes multiple slots, and component feeder 12 can be detachably installed in each slot. Feeder holding section 14 may be fixed to component mounter 10 or may be detachable from component mounter 10. Mounting head 16 detachably holds one or multiple nozzles 6, uses nozzle 6 to pick up electronic components 4 supplied by component feeder 12, and mounts electronic component 4 on board 2. At this time, head moving device 18 moves mounting head 16 with respect to component feeder 12 and board 2. Accordingly, electronic component 4 is picked up from specific component feeder 12 of multiple component feeders 12, and electronic component 4 is mounted on a position determined on board 2 in advance. Board conveyor 20 carries in, supports, and carries out board 2.

Interface device 24 is a device that provides the user with various information on component mounter 10 and is a device that receives an instruction and information from the user. In the present example, interface device 24 is a touch panel, but may include, for example, a display, a key board, and a mouse.

Control device 30 is configured to communicate with management device 50. Control device 30 includes a computer including a memory and CPU. Control device 30 mounts electronic component 4 on board 2 by controlling the operation of each element of component mounter 10 in accordance with an instruction from management device 50.

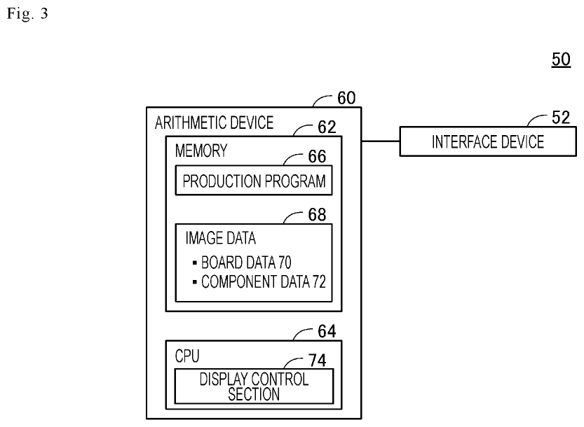

Next, the configuration of management device 50 will be described. As illustrated in FIG. 3, management device 50 includes interface device 52 and arithmetic device 60.

Interface device 52 is a device that provides the user with various information on component mounting line 100 and is a device that receives an instruction and information from the user. In particular, interface device 52 of the present example functions as a device that displays an image of board 2 produced in component mounting line 100 in display region 52a, as described later. In addition, the user can change the image of board 2 to a size desired by the user by performing an operation input to interface device 52. In the present example, interface device 52 is a touch panel, but may include, for example, a display, a keyboard, and a mouse.

Arithmetic device 60 includes a computer including memory 62 and CPU 64. Production program 66 is stored in memory 62. The operation of entire component mounting line 100 is described in production program 66, and arithmetic device 60 instructs the various devices incorporated in component mounting line 100 to perform the operation to be executed by each device according to production program 66. In addition, memory 62 stores image data 68 of board 2 produced by executing production program 66. Image data 68 includes board data 70 and component data 72. Board data 70 includes sub-board information indicating the shape and position of sub-board 3 disposed on board 2. Component data 72 includes body information indicating the shape and position of electronic component 4 mounted on board 2, lead bump information indicating the shape and position of lead and/or bump 5 of electronic component 4, marker information indicating the shape and position of marker 7 indicating the direction of electronic component 4, and character string graphic information indicating the shape and position of character string and/or FIG. 8 printed on electronic component 4. As described above, image data 68 includes board data 70 and component data 72 classified into multiple pieces of information.

A priority order is assigned in advance to each piece of information (each classification) included in board data 70 and component data 72. The priority order is an order indicating a degree of priority to be displayed in display region 52a of interface device 52. That is, the information to which the high priority order is assigned is preferentially displayed in display region 52a. When the size of the image displayed in display region 52a is reduced, the line segment is deformed when the line segment to be displayed based on each piece of information is less than the display unit of display region 52a, so that an image with these pieces of information omitted has to be displayed. In the present example, in view of such a situation, by assigning a priority order to each piece of information, an order in which display is omitted is determined in advance according to a size of an image. In the present example, the first priority order is assigned to the sub-board information, the second priority order is assigned to the body information, the third priority order is assigned to the lead bump information, the fourth priority order is assigned to the marker information, and the fifth priority order is assigned to the character string graphic information.

CPU 64 includes display control section 74 that determines information to be displayed on interface device 52 based on the size of the displayed image and the above-described priority order.

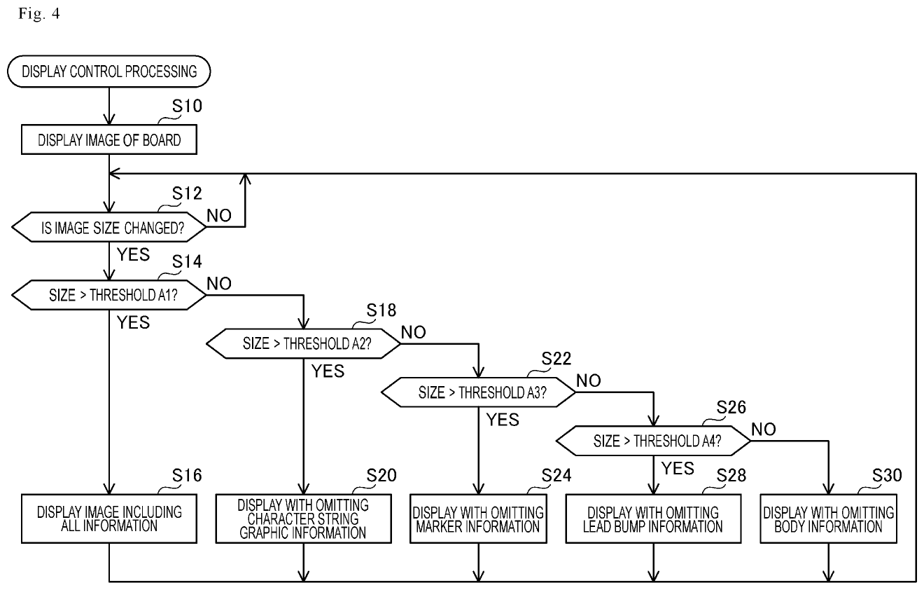

Next, the display control processing executed by CPU 64 will be described. The display control processing illustrated in FIG. 4 is started, for example, when an operation of displaying an image of board 2a produced in component mounting line 100 on interface device 52 is input by the user.

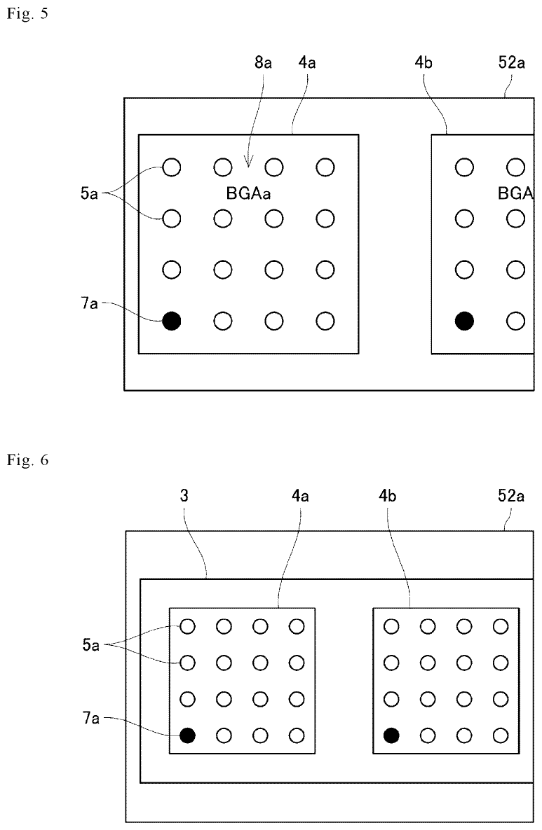

First, in S10, CPU 64 displays an image of board 2a in display region 52a. Here, for example, an image including entire board 2a is displayed. The image displayed in display region 52a in S10 may be displayed with any size. For example, any of the images illustrated in FIGS. 5 to 9 may be displayed. Hereinafter, for convenience of description, it is assumed that one sub-board 3a (refer to FIG. 6 and the like) is disposed on board 2a to be produced, and two electronic components 4a (refer to FIG. 6 and the like) of the same type are mounted.

In S12, CPU 64 determines whether an operation of changing the size of the image of board 2a has been input. When CPU 64 detects the input of the operation of changing the size of the image by the user, the processing proceeds to S14.

In S14, CPU 64 determines whether the size of the image after the change is larger than threshold A1. Threshold A1 is a value larger than thresholds A2 to A5 described later. In a case where the size of the image after the change is larger than threshold A1 (YES in S14), CPU 64 displays all the information included in board data 70 and component data 72 in S16 as illustrated in FIG. 5. That is, in a case where the size of the image designated by the user is large to some extent (in other words, in a case where the image is enlarged and displayed), CPU 64 displays an image including all information (that is, each shape of sub-board 3a, electronic component 4a, bump 5a, marker 7a, and character string 8a). In FIG. 5, the shape of sub-board 3a disposed on board 2a is not actually displayed due to the relationship of the display area of display region 52a.

In S18, CPU 64 determines whether the size of the image after the change is larger than threshold A2. Threshold A2 is smaller than threshold A1. That is, CPU 64 determines whether the size of the image after the change is smaller than threshold A1 and larger than threshold A2. In a case where the size of the image after the change is larger than threshold A2 (YES in S18), CPU 64 displays an image in which the character string graphic information (that is, character string 8a) in component data 72 is omitted as illustrated in FIG. 6 in S20. That is, in a case where the size of the image designated by the user becomes smaller than threshold A1, CPU 64 displays the image in which the information to which the fifth priority order is assigned (that is, the lowest priority order) is omitted.

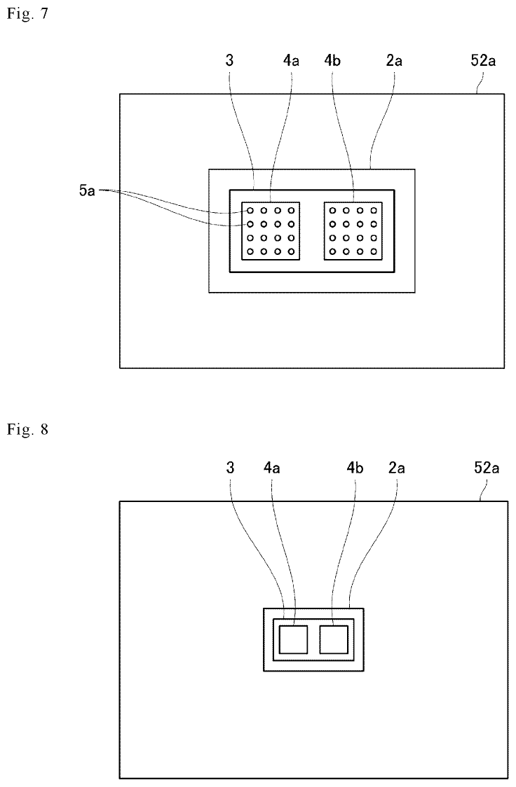

In S22, CPU 64 determines whether the size of the image after the change is larger than threshold A3. Threshold A3 is smaller than threshold A2. That is, CPU 64 determines whether the size of the image after the change is smaller than threshold A2 and larger than threshold A3. In a case where the size of the image after the change is larger than threshold A3 (YES in S22), CPU 64 displays an image in which the marker information (that is, the position of marker 7a) in component data 72 is further omitted as illustrated in FIG. 7 in S24. That is, in a case where the size of the image designated by the user becomes smaller than threshold A2, CPU 64 displays an image in which the information to which the fourth priority order is assigned (that is, the second lowest priority order) is further omitted. In other words, CPU 64 displays an image including only each shape of sub-board 3a, electronic component 4a, and bump 5a.

In S26, CPU 64 determines whether the size of the image after the change is larger than threshold A4. Threshold A4 is smaller than threshold A3. That is, CPU 64 determines whether the size of the image after the change is smaller than threshold A3 and larger than threshold A4. In a case where the size of the image after the change is larger than threshold A4 (YES in S26), CPU 64 displays an image in which the lead bump information (the shape of bump 5a) in component data 72 is further omitted as illustrated in FIG. 8 in S28. That is, in a case where the size of the image designated by the user becomes smaller than threshold A3, the image in which the information to which the third priority order is assigned (that is, the third lowest priority order) is further omitted is displayed. In other words, CPU 64 displays an image including only each shape of sub-board 3a and electronic component 4a.

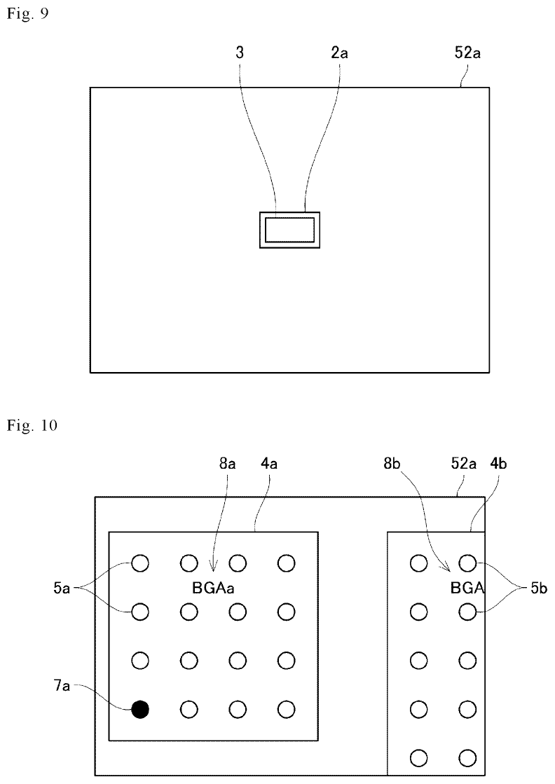

In S30, since CPU 64 determines that the size of the image after the change is smaller than threshold A4 (NO in S26), as illustrated in FIG. 9, CPU 64 displays an image in which the body information (that is, the shape of electronic component 4a) in component data 72 is further omitted. That is, in a case where the size of the image designated by the user becomes smaller than threshold A4, the image in which the information to which the second priority order is assigned (that is, the fourth lowest priority order) is further omitted is displayed. In other words, CPU 64 displays an image including only the shape of sub-board 3a.

As described above, as the size of the image of board 2a becomes smaller, CPU 64 displays the image in which the display of the information having the lower priority order is omitted in order as illustrated in FIGS. 5 to 9. As described above, in the present example, even when the size of the image to be displayed is reduced, the display of the information with a high degree of priority to be displayed (that is, the important element for the user) is not lost, and appropriate information can be provided to the user.

### (Correspondence Relationship)

Component mounter 10 is an example of a “board work machine”. Interface device 52, management device 50, and arithmetic device 60 are examples of a “display section”, a “display device”, and a “control section”, respectively. The marker information and the character string graphic information illustrated in FIGS. 5 and 6 are examples of “first classification” and “second classification”, respectively. The marker and the character string illustrated in FIGS. 5 and 6 are examples of a “first portion” and a “second portion”, respectively.

### Example 2

In Example 1, although the case where board 2a to be produced includes two electronic components 4a of the same type has been described, in Example 2, a case will be described where multiple types of electronic components 4a to 4c (refer to FIG. 12, and the like) are mounted on board 2b to be produced. In the present example, component data 72 corresponding to each of electronic components 4a to 4c is stored in memory 62, and the display control processing illustrated in FIG. 4 is executed for each type of electronic components 4a to 4c. The following description will be continued assuming that thresholds A1 to A5 are used for electronic component 4a, thresholds B1 to B5 are used for electronic component 4b, and thresholds C1 to C5 are used for electronic component 4c. That is, the description will be continued by reading each of thresholds A1 to A5 in FIG. 4 as thresholds B1 to B5 for electronic component 4b, and reading each of thresholds A1 to A5 in FIG. 4 as thresholds C1 to C5 for electronic component 4c. Threshold A, threshold B, and threshold C need not have a mutual relationship. For example, as an example of a partial relationship between threshold A and threshold B, A1>B1>A2, A1>A2>B1, or B1>A1>A2 may be satisfied.

FIGS. 10 to 15 each illustrate a display example of the image after the operation of changing the size of the image of board 2b is input (YES in S12). In the example illustrated in FIG. 10, the size of the image designated by the user is larger than any of threshold A1, threshold B1, and threshold C1 (YES in S14). Therefore, CPU 64 displays an image including all information included in image data 68. In FIG. 10, only a part of electronic component 4b is actually displayed and electronic component 4c is not displayed due to the relationship of the display area of display region 52a.

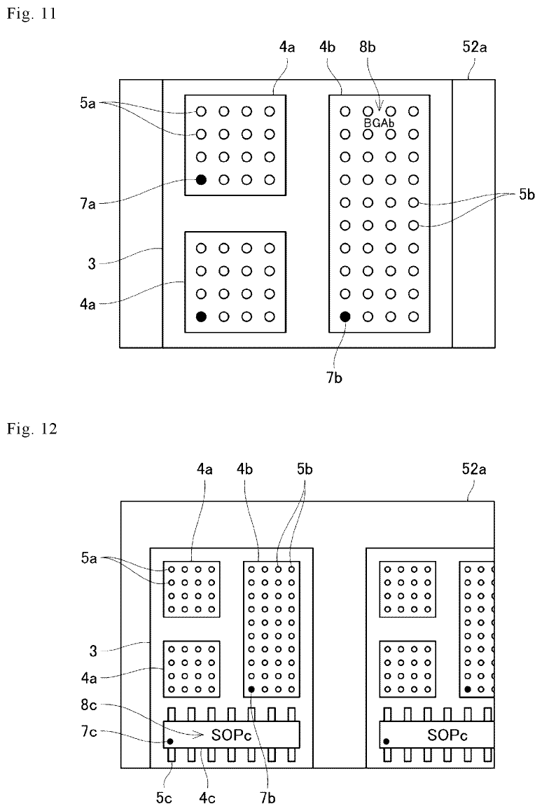

In the example illustrated in FIG. 11, the size of the image designated by the user is smaller than threshold A1 and larger than threshold A2 (YES in S18). In addition, the size is larger than threshold B1 and threshold C1 (YES in S14). Therefore, as compared with FIG. 10, CPU 64 displays an image in which the character string graphic information (that is, character string 8a) of electronic component 4a is omitted, while displaying the character string graphic information (that is, character strings 8b and 8c) of electronic component 4b and electronic component 4c without omission. That is, CPU 64 displays an image including all information for electronic components 4b and 4c.

In addition, in the example illustrated in FIG. 12, the size of the image designated by the user is smaller than threshold A2 and larger than threshold A3 (YES in S22). In addition, the size is smaller than threshold B1 and larger than threshold B2 (YES in S18). In addition, the size is larger than threshold C1 (YES in S14). Therefore, as compared with FIG. 11, CPU 64 displays an image in which the marker information (that is, the position of marker 7a) of electronic component 4a is further omitted and the character string graphic information (that is, character string 8b) of electronic component 4b is omitted, while displaying an image including all information for electronic component 4c.

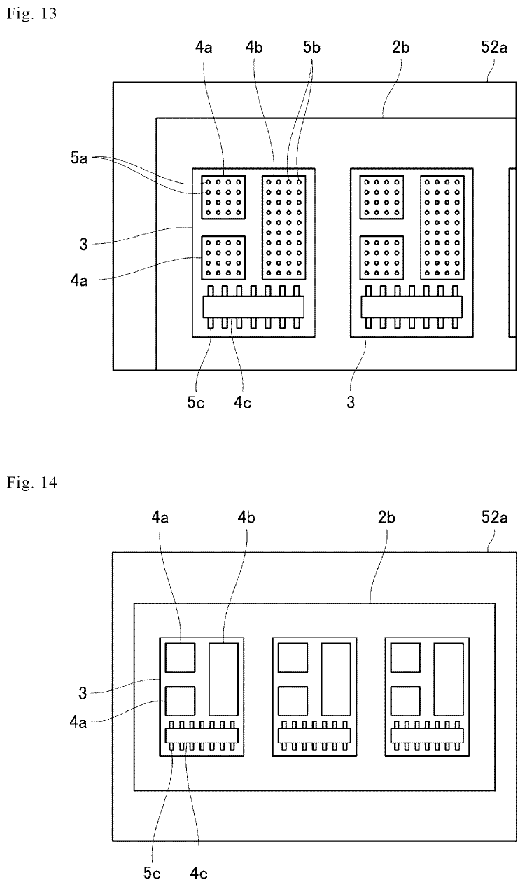

In addition, in the example illustrated in FIG. 13, the size of the image designated by the user is smaller than threshold A2 and larger than threshold A3 (YES in S22). In addition, the size is smaller than threshold B2 and larger than threshold B3 (YES in S22). In addition, the size is smaller than threshold C2 and larger than threshold C3 (YES in S22). Therefore, as compared with FIG. 12, CPU 64 displays an image in which the marker information (the position of marker 7b) is further omitted for electronic component 4b and the character string graphic information and the marker information (that is, character string 8c and the position of marker 7c) are omitted for electronic component 4c. Meanwhile, CPU 64 displays an image similar to that in FIG. 12 (an image in which the character string graphic information and the marker information are omitted) for electronic component 4a.

In addition, in the example illustrated in FIG. 14, the size of the image designated by the user is smaller than threshold A3 and larger than threshold A4 (YES in S26). In addition, the size is smaller than threshold B3 and larger than threshold B4 (YES in S26). In addition, the size is smaller than threshold C2 and larger than threshold C3 (YES in S22). Therefore, as compared with FIG. 13, CPU 64 displays an image in which the lead bump information (that is, bump 5a and bump 5b) is omitted for electronic components 4a and 4b. Meanwhile, CPU 64 displays an image similar to that in FIG. 13 (an image in which the character string graphic information and the marker information are omitted) for electronic component 4c.

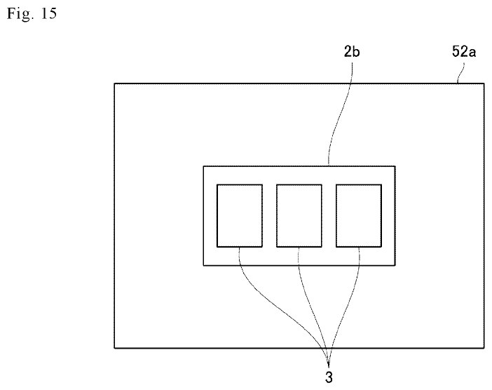

In addition, in the example illustrated in FIG. 15, the size of the image designated by the user is smaller than threshold A3 and larger than threshold A4 (YES in S26). In addition, the size is smaller than threshold B3 and larger than threshold B4 (YES in S26). In addition, the size is smaller than threshold C3 and larger than threshold C4 (YES in S26). Therefore, as compared with FIG. 14, CPU 64 displays an image in which the lead bump information (that is, lead 5c) is omitted for electronic component 4c. That is, CPU 64 displays an image including only the body information (the shapes of electronic components 4a to 4c) for all electronic components 4a to 4c.

As described above, in a case where board 2b includes multiple types of electronic components 4a to 4c, CPU 64 executes the display control processing for each type of electronic components 4a to 4c. That is, CPU 64 determines whether to display information (body information, lead bump information, and the like) belonging to a predetermined classification for each type of electronic components 4a to 4c according to a size of the displayed image. Therefore, in the present example, the information belonging to the same classification is not unevenly omitted for electronic component 4 of the same type, and the user can easily obtain the content of the displayed image.

Although the specific example of the technique disclosed in the present description is described in detail, the specific example is merely an example, and does not limit the claims. The technique described in the claims includes various modifications and changes to the specific examples described above. Hereinafter, modified examples of the above-described example will be listed.

In the above-described example, although the image of board 2 to be produced is displayed on interface device 52 of management device 50, the image may be displayed on interface device 24 of component mounter 10, and an interface device (not illustrated) of another work machine, or may be displayed on a device separate from these devices.

In addition, in the above-described example, an example in which the shape of sub-board 3 disposed on board 2 to be produced, the shape of electronic component 4 mounted on board 2, and the like are displayed has been described. However, for example, in a case where an image of a circuit disposed on board 2 is displayed, the technique disclosed in this description may be applied.

The technical elements described in the present description, or the drawings exhibit technical usefulness independently or in various combinations and are not limited to the combinations described in the claims as originally filed. In addition, the technique exemplified in the present description, or the drawings simultaneously achieves multiple purposes, and achieving one of the purposes itself has technical usefulness.

1. A display device for displaying, on a display section, an image of a board as a target for executing predetermined processing in a board work machine, comprising:
a control section configured to change a size of the image of the board and to display the image on the display section, wherein,
the image includes one or multiple first portions belonging to a first classification and one or multiple second portions belonging to a second classification different from the first classification,
a first priority order is assigned to the first classification,
a second priority order is assigned to the second classification,
the priority order is an order indicating a degree of priority to be displayed on the display section, and
the control section executes display control processing of displaying the image including the first portion and the second portion on the display section in a case where the size of the image to be displayed on the display section is larger than a predetermined value, and
displaying the image including the first portion but not including the second portion on the display section in a case where the size of the image to be displayed on the display section is smaller than the predetermined value.

2. The display device according to claim 1, wherein the first classification and the second classification are any of a shape of a sub-board disposed on the board, a shape of a component mounted on the board, a shape of a lead and a bump of the component, a marker indicating a direction of the component, or a character string or a figure printed on the component.

3. The display device according to claim 1, wherein in a case where the image includes multiple types of components, the control section executes the display control processing for the components for each type.
